(19) United States
(12) Patent Application Publication
(10) Pub. No.: US 2024/0055263 A1
(43) Pub. Date: Feb. 15, 2024

(54) METHOD FOR MANUFACTURING SIGMA-SHAPED GROOVE

(71) Applicant: Shanghai Huali Integrated Circuit Corporation, Shanghai (CN)

(72) Inventors: Lian Lu, Shanghai (CN); Yizheng Zhu, Shanghai (CN); Kai Qian, Shanghai (CN)

(21) Appl. No.: 18/175,092

(22) Filed: Feb. 27, 2023

(30) Foreign Application Priority Data
Aug. 11, 2022 (CN) 202210959786.4

(51) Int. Cl. H01L 21/304; H01L 21/8238

(52) U.S. Cl. CPC H01L 21/3043; H01L 21/823864; H01L 21/823857

(57) ABSTRACT

A method for manufacturing a sigma-shaped groove in a semiconductor substrate includes: step 1: performing the first etching to form a U-shaped groove in a selected area of the substrate; step 2: performing a second etching configured to expand an opening width of the top sub-groove outward laterally, without changing an opening width of the bottom sub-groove and a depth of the groove; and step 3: performing the third etching which has different etching rates on different crystal surfaces of the semiconductor substrate to further expand the groove into a sigma-shaped groove with a sigma-shaped cross section. An increase of the opening width of the top sub-groove shifts the upper side surface towards an outer side of the sigma-shaped groove, resulting in an upward shift of the apex and reduces a vertical spacing between the apex and top surface of the semiconductor substrate, thereby improving the device performance.

### CROSS-REFERENCES TO RELATED APPLICATIONS

This application claims the priority to Chinese patent application No. CN 202210959786.4, filed on Aug. 11, 2022, and entitled “METHOD FOR MANUFACTURING SIGMA-SHAPED GROOVE”, the disclosure of which is incorporated herein by reference in entirety.

### TECHNICAL FIELD

The present application relates to a method for manufacturing a semiconductor integrated circuit, and in particular to a method for manufacturing a sigma-shaped groove.

### BACKGROUND

As the process roadmap nodes continue to reduce the size of IC circuits, in the nominal 40 nm, 28 nm and 22 nm logic processes, due to the reduction of the gate dimensions, P-type devices such as PMOS need to increase the embedded silicon germanium process to improve the device performance. Before the silicon germanium epitaxial layer is embedded, it is necessary to use the dry etching process to carve a shallow trench, i.e., a groove, and then use tetramethylammonium hydroxide (TMAH) wet etching to get a sigma-shaped grooves. The height from the apex to the gate surface at two ends of the sigma-shaped groove has a significant influence on the device. The larger the apex-gate height is, the smaller the acceleration effect of the embedded germanium silicon epitaxial layer on the device performance is, and on the contrary, a smaller apex-gate height gives a larger effect on the device.

The cross section of the sigma-shaped groove has a sigma-shape i.e., a diamond-shape.

The TMAH wet etching process mainly uses the principle of less etching on its (111) crystal orientation on the silicon substrate to obtain the sigma-shaped morphology. A crystal surface corresponding to the (111) crystal orientation is a (111) crystal surface. Therefore, the apex-gate height of the sigma-shaped groove is mainly determined by the morphology after etching.

An etching area is defined by a lithography process first, then performing a traditional dry etching process on the grooves directly to obtain U-shaped groove morphology. In this way, after TMAH wet etching, the apex-gate height of the sigma-shaped groove is relatively large, which is not desired for the device. Refer to FIG. 1A and FIG. 1B, which illustrate structural diagrams of devices in steps of an existing method for manufacturing the sigma-shaped groove. The existing method for manufacturing the sigma-shaped groove includes the following steps:

In step 1, referring to FIG. 1A, a first etching is performed. The first etching forms a groove 108a in a selected area of a silicon semiconductor substrate 101. The first etching is dry etching which makes the groove 108a U-shaped.

Generally, a PMOS device and an NMOS device are integrated on the silicon substrate 101 in an integrated process. The groove 108a is located between two sides of the gate structures of the PMOS devices. Each gate structure includes a gate dielectric layer 102 and a polysilicon gate 103 stacked sequentially. Sidewalls 106 are formed on the side surfaces of the polysilicon gate 103.

A silicon nitride cap layer 104 and a silicon oxide cap layer 105 are usually formed on the top of the polysilicon gate 103.

Step 1 includes additional following steps:

In step 11, a hard mask layer 107 is formed. The hard mask layer 107 on the side surfaces and top surfaces of the gate structures and surfaces of the outer sides of the gate structures.

In step 12, patterning etching is performed on the hard mask layer 107 to open a forming area of the groove 108a.

For the patterning etching of the hard mask layer 107, it is necessary to first define the forming area of the groove 108a in the PMOS device area by adopting a photolithography process. Then, the hard mask layer 107 is patterned by etching as the result of the photolithography process.

Referring to FIG. 1A, after the patterning etching of the hard mask layer 107, the hard mask layer 107 on the side surfaces of the gate structures on the two sides of the groove 108a is retained, in a spacing area between the gate structures, and the hard mask layer 107 on the top area of the groove 108a is removed. The partial areas of the hard mask layer 107 on top of the gate structures are also removed.

In step 13, the first etching is performed by using the hard mask layer 107 to form the groove 108a.

Generally, the second etching is wet etching using tetramethylammonium hydroxide (TMAH) as the etching solution. The etching rates of TMAH on different crystal surfaces of the silicon substrate 101 are different. The etching rate on the (111) crystal surface is much smaller compared with the etching rate on the (110) crystal surface and (100) crystal surface. The top surface of the silicon substrate 101 is usually a (100) crystal surface. Dotted lines 109a and 109b in FIG. 1A represent two (111) crystal surfaces. When the second etching is performed on the groove 108a in FIG. 1A, the side surfaces will stop on the two (111) crystal surfaces corresponding to the dotted lines 109a and 109b. After the second etching, each side surface of the sigma-shaped groove 108 in FIG. 1B has upper side surfaces 1081, lower side surfaces 1082 and each apex 1083 formed by intersection of one upper side surface 1081 and one lower side surface 1082, Both the upper side surfaces 1081 and the lower side surfaces 1082, i.e., the two (111) crystal surfaces corresponding to the dotted lines 109a and 109b in FIG. 1A, are surfaces where the etching rate of the second etching is the lowest. In this existing method, the position of the apex 1083 cannot be well controlled. Generally, the spacing h101 between the apex 1083 and the top surface of the silicon substrate 101 is made to be large. The spacing h101 is the apex-gate height. The spacing h101 has a significant influence on the device performance.

### BRIEF SUMMARY

According to some embodiments in this application, a method for manufacturing the sigma-shaped groove includes:

step 1: performing the first etching, the first etching forms a groove in a selected area of a silicon semiconductor substrate, the first etching is dry etching to make the groove U-shaped;

step 2: performing the second etching to an upper part of the groove, the upper part of the groove comprises a top sub-groove and a bottom sub-groove under the top sub-groove, wherein the second etching is configured to expand an opening width of the top sub-groove outward laterally, without changing an opening width of the bottom sub-groove and a depth of the groove; and; and

step 3: performing the third etching, the third etching adopts different etching rates on different crystal surfaces of the silicon silicon semiconductor substrate and expands the groove into a sigma-shaped cross section, each side surface of the sigma-shaped groove has an upper side surface, a lower side surface and an apex line formed by intersection of the upper side surface and the lower side surface, both the upper side surface and the lower side surface are surfaces where the etching rate of the third etching is the lowest, the increase of the width of the top sub-groove makes the upper side surface recess back towards an outer side of the sigma-shaped groove and makes the apex recess upwards, the upward movement of the apex decreases the vertical first spacing between the apex and the top surface of the silicon semiconductor substrate.

In some cases, step 1 further includes the following steps:
step 11: forming a hard mask layer;
step 12: performing patterning etching on the hard mask layer to open a forming area of the groove; and
step 13: performing the first etching by using the hard mask layer as a mask to form the groove.

In some cases, step 2 further includes the following steps:
step 21: forming a first filling layer to fill the groove and extend to an external surface of the groove;
step 22: performing back etching on the first filling layer and stop at the bottom sub-groove so that to expose the silicon on side surfaces of the groove at the top area of the bottom sub-groove;
step 23: performing the second etching which is an isotropic etching on the silicon surface exposed on top of the bottom sub-groove to form the top sub-groove; and
step 24: removing the first filling layer.

In some cases, the first filling layer is formed by adopting a coating process.

In some cases, the first filling layer is formed of a material which may include photoresist, Bottom Anti-Reflective Coating (BARC), Spin On Carbon (SOC), Organic Under Layer (ODL) or Deep UV Light Absorbing Oxide (DUO).

In some cases, the silicon semiconductor substrate is a silicon substrate and the top surface of the silicon semiconductor substrate is a (100) crystal surface; in step 3, the etching rates of the third etching decrease on crystal surfaces in the order of the (110) surface, the (100) surface to the (111), and after the third etching is completed, both the upper side surface and the lower side surface of each side of the sigma-shaped groove are (111) crystal surfaces.

In some cases, in step 3, the third etching is wet etching and the wet etching solution for the third etching includes TMAH.

In some cases, in step 1, the groove is located between two sides of gate structures.

In some cases, a PMOS and an NMOS are integrated on the silicon semiconductor substrate at the same time, and the groove is located between two sides of the gate structures of the PMOS; the sigma-shaped groove is used for filling an embedded silicon germanium epitaxial layer, and the vertical first spacing is the apex-gate height. The smaller the vertical first spacing is, the higher the carrier mobility of a conductive channel of the PMOS has.

In some cases, in step 11, the hard mask layer covers side surfaces and top surfaces of the gate structures and surfaces of outer sides of the gate structures.

In some cases, step 12 includes the following steps:
performing a first photolithography process to form an opening in the first photoresist, located in the area of the PMOS over the forming area of the groove; and
performing etching on the hard mask layer by using the first photoresist pattern as a mask to remove part of the hard mask layer all the way to the surface of the silicon semiconductor substrate in the forming area of the groove.

In some cases, during the first photolithography process, the first photoresist pattern goes through photo exposing and developing the first photoresist layer;

before the first photoresist layer is coated, the method further includes a step of coating a first organic anti-reflective coating layer, the first organic anti-reflective coating layer fills the spacing area between the gate structures and extends to the hard mask layer on top of the gate structures; the first photoresist layer is coated on the surface of the first organic anti-reflective coating layer;

after the first photoresist pattern is formed, the first organic anti-reflective coating layer is etched first and then the hard mask layer is etched.

In some cases, in step 12, the opening of the first photoresist pattern is wider than the opening width of the spacing area between the gate structures, and the spacing area between the gate structures is fully opened after the etching;

after the hard mask layer is etched, in the spacing area between the gate structures, the hard mask layer on top of the groove is removed while leaving the hard mask layer on side surfaces of the gate structures on the two side walls of the groove retained.

In some cases, in step 21, the first filling layer fills the spacing area between the gate structures and further extend to cover a part of the hard mask layer on top of the gate structures.

In some cases, the thickness of the first filling layer is in a range of 500 Å-4000 Å.

In some cases, each gate structure includes a gate dielectric layer and a polysilicon gate stacked sequentially, and side walls are formed on side surfaces of the polysilicon gate.

In some cases, in step 2, the opening width of the top sub-groove is in a range of 5 Å-200 Å more than the opening width of the top area of the groove before the second etching.

In some cases, in step 24, after the first filling layer is removed, the method further includes a step of performing cleaning.

In the present application, after the first etching is performed to form a U-shaped groove, the third etching with different etching rates on crystal surfaces is not directly performed on the groove, but the second etching is performed to expand the opening width of the top area of the groove without changing the opening width of the bottom area of the groove and the depth of the groove. In this way, in the third etching, the upper side surface of the top sub-groove above the apex points of the sigma-shaped groove will be outwardly expanded, under the condition that the width of the bottom sub-groove and the depth of the groove are kept unchanged, so that the position of the apex points formed by the intersection of the upper side surface and the lower side surface will shift upwards with the outward movement of the upper side surface, thus reducing the spacing, i.e., the vertical first spacing between the apex and the top surface of the silicon semiconductor substrate.

In the present application, the vertical first spacing is applied in the semiconductor device to improve the device performance. For example, the sigma-shaped groove is usually used as the filling area of the embedded epitaxial layer on the two sides of the gate structures of the PMOS. The vertical first spacing is the apex-gate height. The smaller the vertical first spacing is, the higher the carrier mobility of the embedded epitaxial layer to the conductive channel at the bottoms of the gate structures of the PMOS is, and the better the electrical performance of the PMOS is. Therefore, the electrical performance of the PMOS can be improved finally.

### BRIEF DESCRIPTION OF THE DRAWINGS

The present application will be further described in detail in combination with the specific embodiments with reference to the drawings.

FIG. 1A and FIG. 1B illustrate cross sectional views of the device structures during steps of an existing method for manufacturing a sigma-shaped groove.

FIG. 2 illustrates a flowchart of a method for manufacturing a sigma-shaped groove according to an embodiment of the present application.

FIG. 3A to FIG. 3H illustrate cross sectional views of the device structures during steps of the method for manufacturing the sigma-shaped groove according to an embodiment of the present application.

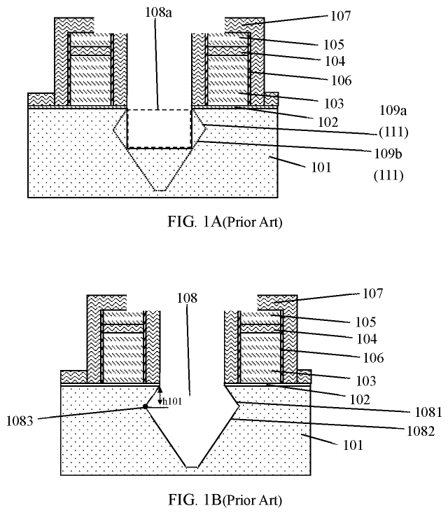

### DETAILED DESCRIPTION OF THE APPLICATION

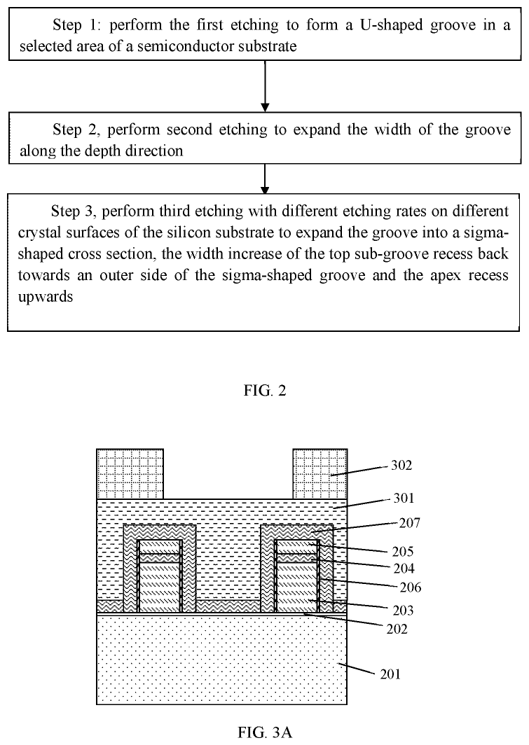

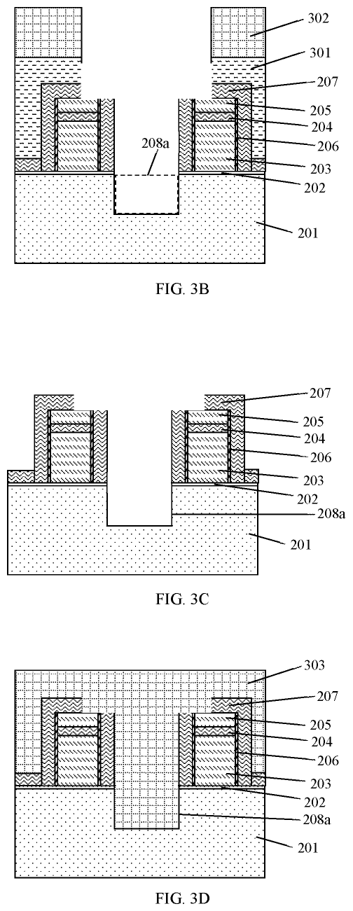

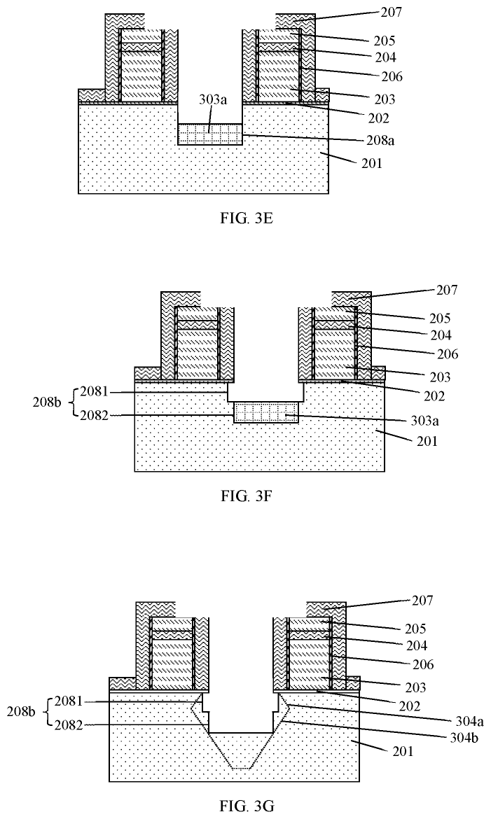

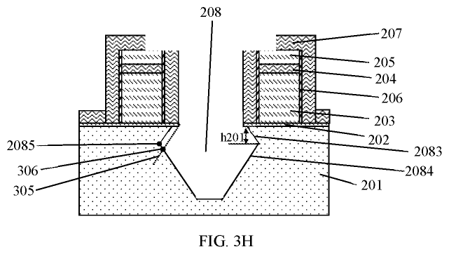

Referring to FIG. 2, it illustrates a flowchart of a method for manufacturing a sigma-shaped groove according to an embodiment of the present application. Referring to FIG. 3A to FIG. 3G, which illustrate cross sectional views of the device structures during steps of a method for manufacturing a sigma-shaped groove 208 (in FIG. 3H) according to an embodiment of the present application. The method for manufacturing the sigma-shaped groove 208 according to the embodiment of the present application includes the following steps:

In step 1, referring to FIG. 3B, first etching is performed. The first etching forms a groove 208a in a selected area of a silicon semiconductor substrate 201. The first etching is dry etching to make the groove 208a U-shaped.

In the embodiment of the present application, step 1 includes the following steps:

In step 11, referring to FIG. 3A, a hard mask layer 207 is formed.

In some embodiments, the groove 208a is located in two sides of gate structures.

In some exemplarily embodiments, a PMOS and an NMOS are integrated on the silicon semiconductor substrate 201 at the same time, and the groove 208a is located between two sides of the gate structures of the PMOS.

The hard mask layer 207 is disposed on side surfaces and top surfaces of the gate structures and surfaces of outer sides of the gate structures.

Each gate structure includes a gate dielectric layer 202 and a polysilicon gate 203 stacked sequentially, and side walls 206 are formed on side surfaces of the polysilicon gate 203.

A silicon nitride cap layer 204 and a silicon oxide cap layer 205 are also formed on top of the polysilicon gate 203.

The sigma-shaped groove provides an area for an embedded silicon germanium epitaxial layer. A vertical first spacing is defined as the apex-gate height.

In step 12, the hard mask layer 207 is patterned to open an area to form the groove 208a.

In some exemplary embodiments, step 12 includes the following steps:

A first photolithography process is performed to form a first photoresist pattern 302. An opening of the first photoresist pattern 302 is located in a forming area of the PMOS and opens the forming area of the groove 208.

In the first photolithography process, the first photoresist pattern 302 is formed by exposing and developing a first photoresist layer.

Before the first photoresist layer is coated, the method further includes a step of coating a first organic anti-reflective coating layer 301. The first organic anti-reflective coating layer 301 fills a spacing area between the gate structures and extends to the hard mask layer 207 on top of the gate structures. The first photoresist layer is coated on a surface of the first organic anti-reflective coating layer 301.

Etching is performed on the hard mask layer 207 by using the first photoresist pattern 302 to remove the hard mask layer 207 from the surface of the silicon semiconductor substrate 201 in the forming area of the groove 208a, so as to realize the patterning of the hard mask layer 207.

When the first organic anti-reflective coating layer 301 is coated and before the hard mask layer 207 is etched, the first organic anti-reflective coating layer 301 has to be etched. In the embodiment of the present application, the etching process of the hard mask layer 207 and the first organic anti-reflective coating 301 is dry etching.

Referring to FIG. 3A, the opening width of the first photoresist pattern 302 is more than the width of the spacing area between the gate structures and the spacing area between the gate structures is fully opened.

Referring to FIG. 3B, after the hard mask layer 207 is etched, in the spacing area between the gate structures, the hard mask layer 207 on side surfaces of the gate structures on the two side walls of the groove 208a is retained, that is, in the opening area of the first photoresist pattern 302, the hard mask layer 207 is self-aligned and retained, on the side surfaces of the gate structures; the hard mask layer 207 is removed from the top of the groove 208a. The hard mask layer 207 is also removed from partial top areas of the gate structures.

In step 13, referring to FIG. 3B, the first etching is performed by using the hard mask layer 207 as a mask to form the groove 208a.

Referring to FIG. 3C, the method thereafter further includes:

A dry stripping process is performed to remove the first photoresist pattern 302 and the first organic anti-reflective coating layer 301, and then wet cleaning is performed to remove the residual polymers.

In step 2, referring to FIG. 3F, the second etching is performed. The second etching expands the opening width of the top area of the groove 208a. The groove after the top opening expansion is referred to numeral 208b. The total depth of the groove 208b is unchanged. A top part where an opening of the groove 208b is expanded is named as a top sub-groove 2081, a bottom area under the top sub-groove 2081 is a bottom sub-groove 2082. The groove 208b is formed by superposing the bottom sub-groove 2082 and the top sub-groove 2081.

In the embodiment of the present application, step 2 further includes the following steps:

In step 21, referring to FIG. 3D, a first filling layer 303 fills the groove 208a and extends to an external surface of the groove 208a.

The first filling layer 303 is formed by adopting a coating process.

In the embodiment of the present application, the material of the first filling layer 303 is photoresist. In other embodiments, the material of the first filling layer 303 can also include BARC, SOC, ODL or DUO.

The first filling layer 303 is further required to fill the spacing area between the gate structures and extend to the gate structures to cover the hard mask layer 207 on top of the gate structures.

In some exemplary embodiments, the thickness of the first filling layer 303 is in the range of 500 Å-4000 Å.

In step 22, referring to FIG. 3E, back etching is performed on the first filling layer 303 to fill the bottom sub-groove 2082, and to expose silicon from side surfaces of the groove 208a on top of the bottom sub-groove 2082.

In step 23, referring to FIG. 3F, the isotropic second etching is performed to on exposed silicon from the top of the bottom sub-groove 2082, so to form the top sub-groove 2081.

In some exemplary embodiments, the opening width of the top sub-groove 2081 is in a range of 5 Å-200 Å, this opening is wider than the opening width of the top area of the groove 208 before the second etching.

In step 24, referring to FIG. 3G, the first filling layer 303a is removed.

After the first filling layer 303a is removed, the method further includes a step of performing cleaning.

In step 3, referring to FIG. 3H, third etching is performed. The third etching adopts different etching rates on different crystal surfaces of the silicon semiconductor substrate 201 and expands the groove 208b into a sigma-shaped groove 208 with a sigma-shaped cross section. In FIG. 3H, the sigma-shaped groove is referred to with a numeral 208. Each side surface of the sigma-shaped groove 208 contains an upper side surface 2083, a lower side surface 2084 and an apex 2085 which is formed by intersection of the upper side surface 2083 and the lower side surface 2084. Both the upper side surface 2083 and the lower side surface 2084 are surfaces where the etching rates of the third etching are the lowest among that of other crystal orientations. The expansion of the width of the top sub-groove 2081 shifts the upper side surface 2083 outwards toward the outer side of the sigma-shaped groove 208, thus shifts the apex point 2085 upwards. The upward shift of the apex 2085 reduces vertical first spacing first spacing h201 between the apex point 2085 and the top surface of the silicon semiconductor substrate 201.

In the embodiment of the present application, the silicon semiconductor substrate 201 is a silicon substrate and the top surface of the silicon semiconductor substrate 201 is a (100) crystal surface.

The etching rates of the third etching on a (110) surface, a (100) surface and a (111) crystal surface decrease sequentially. That is, the etching rate of the third etching on the (111) crystal surface is the lowest and it basically stops on the (111) crystal surface. Both the crystal surfaces corresponding to dotted lines 304a and 304b in FIG. 3G are (111) crystal surfaces. After the third etching is completed, it stops on the crystal surfaces corresponding to the dotted lines 304a and 304b. Referring to FIG. 3H, after the third etching is completed, both the upper side surface 2083 and the lower side surface 2084 of each side surface of the sigma-shaped groove 208 are respectively crystal surfaces corresponding to the dotted lines 304a and 304b in FIG. 3G.

In the embodiment of the present application, the third etching is wet etching and wet etching solution for the third etching includes TMAH. In other embodiments, the third etching may also adopt wet etching solution or dry etching, which can only meet the requirement of decreasing the etching rate on the (110) surface, (100) surface and (111) crystal surface sequentially.

Referring to 3H, the dotted line 305 represents the position of the upper side surface formed by the third etching when the width of the top sub-groove 2081 is not expanded. It can be seen that the apex 306 formed by the dotted line 305 and the lower side surface 2084 is lower than the apex 2085.

In some exemplary embodiments, the sigma-shaped groove 208 is used for filling an embedded silicon germanium epitaxial layer. The vertical first spacing h201 is the apex-gate height. The shorter the vertical first spacing h201 is, the higher the carrier mobility of the conductive channel of the PMOS is.

In the present application, after the first etching is performed to form a U-shaped groove 208a, the third etching with different etching rates on crystal surfaces is not directly performed on the groove 208a, but the second etching is performed to make the opening width of the top area of the groove 208a expanded and make the opening width of the bottom area of the groove 208a and the depth of the groove 208a unchanged. In this way, in the third etching, the upper side surface 2083 above the apex 2085 of the sigma-shaped groove 208 will be expanded with the outward expansion of the side surface of the top sub-groove 2081, and the position of the lower side surface 2084 below the apex 2085 of the sigma-shaped groove 208 will be kept unchanged under the condition that the width of the bottom sub-groove 2082 and the depth of the groove 208a are kept unchanged, so that the position of the apex 2085 formed by the intersection of the upper side surface 2083 and the lower side surface 2084 will move upwards with the outward movement of the upper side surface 2083, thus reducing the vertical first spacing h201 between the apex 2085 and the top surface of the silicon semiconductor substrate 201.

In the present application, the vertical first spacing h201 is applied in the semiconductor device to improve the device performance. For example, the sigma-shaped groove 208 is usually used as the filling area of the embedded epitaxial layer on the two sides of the gate structures of the PMOS. The vertical first spacing h201 is the apex-gate height. The shorter the vertical first spacing h201 is, the higher the carrier mobility is in the embedded epitaxial layer to the conductive channel at the bottoms of the gate structures of the PMOS, so the better the electrical performance of the PMOS will be. Therefore, this technique improves the electrical performance of the PMOS.

The present application has been described in detail through the above specific embodiments, which, however, do not constitute limitations to the present application. Without departing from the principle of the present application, those skilled in the art may make many changes and improvements, which should also be considered as falling within the scope of protection of the present application.

What is claimed is:

1. A method for manufacturing a sigma-shaped groove in a silicon semiconductor substrate, comprising:
step 1: performing a first etching, wherein the first etching forms a groove in a selected area of the silicon semiconductor substrate, wherein the first etching is dry etching, and wherein the groove is configured to be U-shaped;
step 2: performing a second etching to an upper part of the groove, wherein the upper part of the groove comprises a top sub-groove and a bottom sub-groove under the top sub-groove, wherein the second etching is configured to expand an opening width of the top sub-groove outward laterally, without changing an opening width of the bottom sub-groove and a depth of the groove; and
step 3: performing a third etching, wherein the third etching adopts different etching rates on different crystal surfaces of the semiconductor substrate, and wherein the third etching is configured to form a sigma-shaped cross section for the groove, wherein each side surface of the sigma-shaped groove comprises an upper side surface, a lower side surface and an apex formed by intersection of the upper side surface and the lower side surface, wherein the third etching has an etching rate being a lowest on both the upper side surface and the lower side surface than that on other surfaces, wherein an increase of the opening width of the top sub-groove shifts the upper side surface towards an outer side of the sigma-shaped groove, resulting in an upward shift of the apex, wherein the upward shift of the apex reduces a vertical first spacing between the apex and a top surface of the semiconductor substrate.

2. The method for manufacturing the sigma-shaped groove according to claim 1, wherein step 1 comprises following steps:
step 11: forming a hard mask layer;
step 12: performing patterning on the hard mask layer to open a forming area of the groove; and
step 13: performing the first etching on the patterned hard mask layer to form the groove.

3. The method for manufacturing the sigma-shaped groove according to claim 2, wherein step 2 further comprises following steps:
step 21: forming a first filling layer to fill the groove, wherein the first filling layer extends to an external surface of the groove;
step 22: performing back etching on the first filling layer, wherein the first filling layer is configured to fill the bottom sub-groove and expose silicon on a side surface of the groove from a top of the bottom sub-groove;
step 23: performing the second etching to form the top sub-groove on silicon exposed on the top of the bottom sub-groove, wherein the second etching comprises isotropic etching; and
step 24: removing the first filling layer.

4. The method for manufacturing the sigma-shaped groove according to claim 3, wherein the first filling layer is formed by adopting a coating process.

5. The method for manufacturing the sigma-shaped groove according to claim 4, wherein a material of the first filling layer comprises photoresist, BARC, SOC, ODL or DUO.

6. The method for manufacturing the sigma-shaped groove according to claim 3, wherein the semiconductor substrate is a silicon substrate, wherein the top surface of the semiconductor substrate is a (100) crystal surface; wherein in step 3, the etching rates of the third etching on a (110) surface, a (100) surface and a (111) crystal surface decrease sequentially, and wherein after the third etching is completed, both the upper side surface and the lower side surface of each side surface of the sigma-shaped groove are (111) crystal surfaces.

7. The method for manufacturing the sigma-shaped groove according to claim 6, wherein in step 3, wherein the third etching is wet etching and a wet etching solution for the third etching comprises TMAH.

8. The method for manufacturing the sigma-shaped groove according to claim 6, wherein in step 1, the groove is located between two sides of gate structures.

9. The method for manufacturing the sigma-shaped groove according to claim 8, wherein a PMOS and an NMOS are formed in an integrated process on the semiconductor substrate, and wherein the groove is located between two sides of gate structures of the PMOS; wherein the sigma-shaped groove provides a space for an embedded silicon germanium epitaxial layer, and wherein the vertical first spacing constitutes the apex-gate height.

10. The method for manufacturing the sigma-shaped groove according to claim 9, wherein in step 11, the hard mask layer is disposed on side surfaces and top surfaces of the gate structures and surfaces of outer sides of the gate structures.

11. The method for manufacturing the sigma-shaped groove according to claim 10, wherein step 12 further comprises following steps:
performing a first photolithography process to form a first photoresist pattern, wherein an opening of the first photoresist pattern is located in a forming area of the groove and a forming area of the PMOS; and
performing etching on the hard mask layer by using the first photoresist pattern to remove the hard mask layer from the surface of the semiconductor substrate in the forming area of the groove.

12. The method for manufacturing the sigma-shaped groove according to claim 11, wherein in the first photolithography process, the first photoresist pattern is formed by exposing and developing the first photoresist layer;
before the first photoresist layer is coated, the method further comprises a step of coating a first organic anti-reflective coating layer, wherein the first organic anti-reflective coating layer fills a spacing area between the gate structures and extends to the hard mask layer on top of the gate structures; wherein the first photoresist layer is coated on a surface of the first organic anti-reflective coating layer; and
after the first photoresist pattern is formed, the first organic anti-reflective coating layer is etched first and then the hard mask layer is etched.

13. The method for manufacturing the sigma-shaped groove according to claim 11, wherein in step 12, the opening width of the first photoresist pattern is more than the width of the spacing area between the gate structures and the spacing area between the gate structures is opened; and
wherein after the hard mask layer is etched, in the spacing area between the gate structures, the hard mask layer on side surfaces of the gate structures on the two sides of the groove is retained, and the hard mask layer is removed from a top of the groove.

14. The method for manufacturing the sigma-shaped groove according to claim 10, wherein in step 21, the first filling layer further fills the spacing area between the gate structures and extends to the gate structures to cover the hard mask layer on top of the gate structures.

15. The method for manufacturing the sigma-shaped groove according to claim 14, wherein a thickness of the first filling layer is in a range of 500 Å-4000 Å.

16. The method for manufacturing the sigma-shaped groove according to claim 8, wherein each of the gate structures comprises a gate dielectric layer and a polysilicon gate stacked sequentially, and wherein side walls are formed on side surfaces of the polysilicon gate.

17. The method for manufacturing the sigma-shaped groove according to claim 1, wherein in step 2, the opening width of the top sub-groove is in a range of 5 Å-200 Å, wherein the opening width of the top sub-groove is larger than an opening width of the top area of the groove before the second etching.

18. The method for manufacturing the sigma-shaped groove according to claim 3, wherein in step 24, after removing the first filling layer, the method further comprises a step of performing cleaning.
